(19) United States
(12) Patent Application Publication
(10) Pub. No.: US 2015/0057882 A1
(43) Pub. Date: Feb. 26, 2015

(54) CONTROL METHOD OF CONTROL DEVICE FOR CONTROLLING DAYTIME RUNNING LIGHT OF VEHICLE

(71) Applicant: Cheng Chung Ho, Taichung City 407 (TW)

(72) Inventor: Cheng Chung Ho, Taichung City 407 (TW)

(21) Appl. No.: 14/344,622

(22) PCT Filed: Oct. 24, 2011
(86) PCT No.: PCT/CN2011/081169

§ 371 Date: Oct. 14, 2014

(51) Int. Cl. B60Q 1/28; G01R 31/36

(52) U.S. Cl. CPC B60Q 1/28; G01R 31/3606; B60Q 2400/30
USPC 701/36

(57) ABSTRACT

Disclosed are a control device and a control method for vehicular daytime running lights. The control device comprises a sampling module and a controller, wherein the sampling module is electrically connected to a storage battery (32) of the automobile, and continuously samples the voltage of the storage battery (32); and the controller is electrically connected to the sampling module and has a processing unit (22) and a memory (24), and an input/output unit (26). The processing unit (22) analyses changes in the sampled voltage, determines whether or not the automobile has started up and whether or not the power generator (34) is operating. The control device and the control method can make the control of daytime running lights more accurate and more stable, and are not affected by the ageing of the storage battery and surroundings.

### BACKGROUND OF THE INVENTION

1. Field of the Invention

The invention relates to a technical field of power control, and more particularly to a control method of an automatic control device for lighting or extinguishing of daytime running light of a vehicle.

2. Related Art

In order to enhance the visibility upon daytime running and to effectively decrease the probability of occurrence of traffic accident, Economic Commission for Europe (ECE R87) has requested all new vehicles, including cars, trucks and large vehicles, for example, to have dedicated daytime running light (DRL). The daytime running light is disposed on the front side of the vehicle, and the associated rule requests to light the daytime running light in the daytime when the vehicle engine starts. The purpose thereof is to warn the walker to notice the vehicle with the starting engine in the daytime. Among the practical methods for recognizing the engine's operation to light the daytime running light includes, the judgement is made by detecting the voltage variation of the battery of the vehicle. Because the vehicle has the starting engine for driving the generator to generate the electric power to charge the battery, the operation of the engine can be reversely determined according to the battery voltage variation.

FIG. 1 shows the voltage waveform of the typical battery. The initial voltage V1 is present when the generator does not operate. After the generator is started, the voltage drop phenomenon is caused so that the voltage falls to V2. Then, the voltage gradually rises to the operation voltage V3 and operation ripples Q are formed, wherein V3>V1>V2.

FIG. 2 shows the voltage waveform of another battery, wherein the initial voltage V1 is present when the generator does not operate. After the generator is started, the voltage gradually rises to the operation voltage V3 and the operation ripples Q are thus formed.

The reasons causing the different voltage waveforms include the vehicle model or the vehicle design, and the factor of different environments.

Taiwan Patent No. M397337 discloses an electric control device of the daytime running light. The electric control device is coupled to the daytime running light and the electronic apparatus of the vehicle to control the daytime running light and the electronic apparatus to turn on or off. The electric control device can detect the output voltage of the vehicle battery. When the output voltage is equivalent to the starting voltage of the engine, a reset signal is outputted to reset an engine-operation judging circuit (ripple detection circuit). When an operation ripple is present on the power signal of the vehicle battery, a power-on signal is generated to power on the electronic apparatus of the vehicle, and whether the light of the vehicle is turned on is detected. When the light of the vehicle is not turned on, the daytime running light is automatically turned on.

Because the above-mentioned technology has a constant reference voltage on the hardware settings, the above-mentioned technology cannot generate a reset signal to start the ripple detection circuit until a voltage dropping state is generated (see V2 of FIG. 1). In other words, if no voltage drop is generated when the vehicle starts (see FIG. 2), the above-mentioned technology of the method of starting the daytime running light cannot operate correctly and thus cannot satisfy the requirements of various types of vehicles.

Also, when the engine stops, the operation ripple of the engine may decrease or disappear, but the voltage of the battery is not necessarily equal to the first voltage. The voltage may be higher than the first voltage, so that the daytime running light cannot be turned off.

### SUMMARY OF THE INVENTION

An object of the invention is to provide a control device and a control method for a daytime running light of a vehicle, wherein the method can precisely judge whether the vehicle starts and whether the generator operates. In addition, the analog and digital operations can be integrated in a dedicated integrated circuit.

The control device for controlling the daytime running light according to the invention includes a sampling module and a controller, wherein the sampling module is electrically connected to a battery of the vehicle and performs continuously voltage sampling on the battery to obtain a plurality of sampling voltages. The controller electrically connected to the sampling module has a processing unit electrically connected to a memory and an input/output unit. The sampling voltages, obtained from the sampling module, are continuously recorded in the memory of the controller and are calculated by the processing unit to analyze the continuity variation of the sampling voltages, so that whether the vehicle starts and whether the generator operates can be precisely judged.

Furthermore, the control method of the invention for controlling the daytime running light of the vehicle performs the continuously sampling on the voltage waveform of the battery to obtain a plurality of sampling voltages. Then, the sampling voltages and the waveform composed thereof are continuously recorded in the memory of the controller. Next, the processing unit of the controller performs analysis and calculation on the variation of waveform continuity. Finally, it is judged whether the vehicle starts according to the analysis and calculation results of the variation of waveform continuity. When the vehicle starts and no external auxiliary input signal is present (e.g., no signal is inputted and the main light or position light are not turned on), the daytime running light can be automatically turned on, and the voltage waveform of the battery is continuously sampled and recorded.

### BRIEF DESCRIPTION OF THE DRAWINGS

FIG. 1 shows a voltage waveform for engine start/stop on a conventional battery.

FIG. 2 shows a voltage waveform for engine start/stop on another conventional battery.

FIG. 3 is a schematic block diagram showing the architecture of the invention.

FIG. 4 shows the flow chart of usage of the invention.

FIG. 5 shows waveform data of the sampling voltages of the invention.

FIG. 6 shows waveform data of the sampling voltages of another embodiment of the invention.

### DESCRIPTION OF MAIN SYMBOLS

| | |
|---|---|
| (10) sampling module | (12) sampling amplifier |
| (14) electronic component | (20) controller |

| | |
|---|---|
| (22) processing unit | (24) memory |

| | |
|---|---|
| (26) input/output unit | (32) battery |

| | |
|---|---|
| (34) generator | (36) daytime running light |
| | driving circuit |

| | |
|---|---|
| (38) daytime running light | (40) analog-to-digital converter |

### DETAILED DESCRIPTION OF THE INVENTION

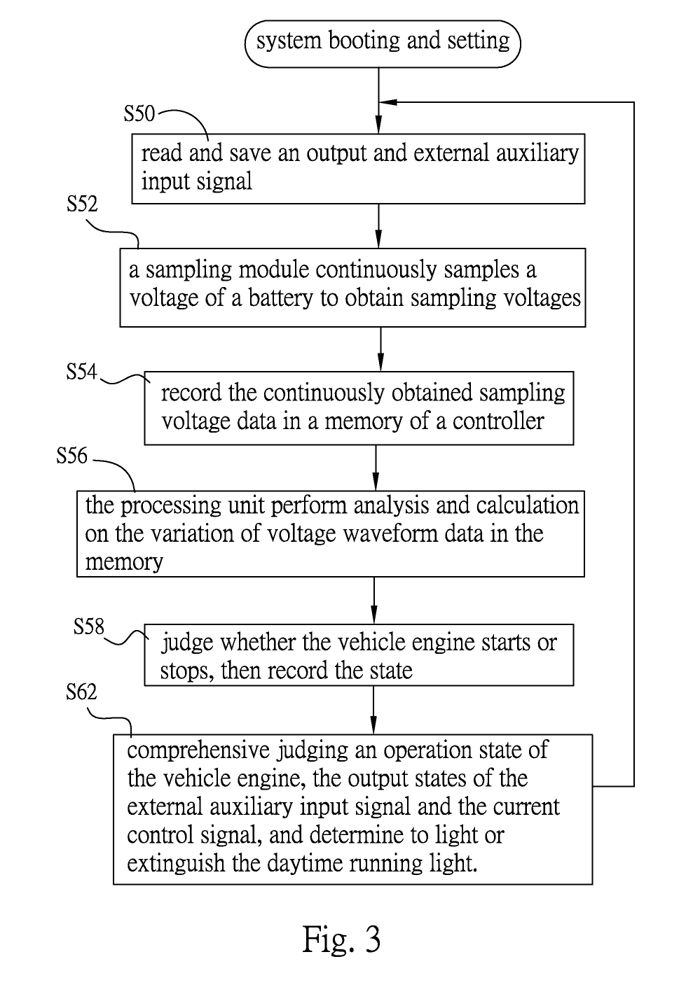

Referring to FIG. 3, a control device of the invention includes a sampling module (10) and a controller (20) electrically connected to the sampling module (10).

The sampling module (10) is electrically connected to a battery (32) and a generator (34). The sampling module (10) has a sampling amplifier (12) and electronic components (14), such as resistors, capacitors, inductors or the like, working in conjunction therewith.

The controller (20) is electrically connected to a daytime running light driving circuit (36), and daytime running light (38) is electrically connected to the daytime running light driving circuit (36).

The sampling module (10) is a voltage sampling element, which may continuously sample the voltage waveform of the battery (32), and more particularly perform the precise sampling by an analog circuit. It is to be noted that no fixed reference value is set in advance in the sampling module (10). Therefore, each time the sampling voltage directly enters the analog-to-digital converter (ADC) (40), the ADC (40) converts the sampling voltage into digital data, whereby the continuous voltage sampling data forms the voltage waveform information. The voltage waveform information, generated from the sampling voltages, has the variation trend of the voltage data equivalent to the variation trend of the voltage of the battery.

The controller (20) has a processing unit (22) electrically connected to a memory (24) and an input/output unit (26). The input/output unit (26) is electrically connected to the daytime running light driving circuit (36).

The sampling voltage, obtained by the sampling module (10) on the battery (32), is converted into digital data by the analog-to-digital converter (ADC) (40). The digital data is recorded in the memory (24), and can be calculated and analyzed by the processing unit (22) so that the continuity variation of the voltage can be obtained.

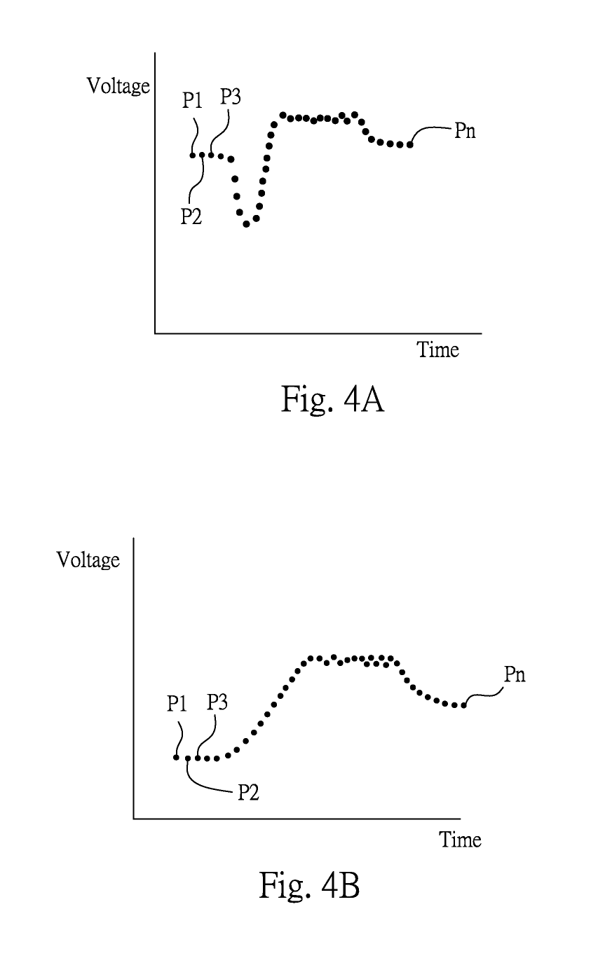

Referring to FIG. 4, the method for controlling the daytime running light using the control device of the invention includes the following steps.

First, the system is boosted and set. In addition, as shown in step S50, the system starts to read and output an auxiliary signal (external auxiliary input signal), and saves the 5, status of auxiliary signal.

Step S52 is a sampling step, in which the sampling module is utilized to continuously sample the voltage of the battery, and accordingly obtain a plurality of sampling voltages. It is to be noted that even if the generator has been started, the sampling operation is still continuously performed.

Step S54 is a continuous recording step, in which the continuously obtained sampling voltage data is recorded in the memory of the controller. At this time, a sampling voltage waveform is equivalent to a waveform of the actual output voltage of the battery.

Step S56 is an analyzing calculating step, in which the processing unit of the controller is utilized to perform analysis and calculation on the data variation of the voltage waveform in the memory.

Step S58 is a judging step of judging whether the vehicle engine starts or stops according to the analysis and calculation results of the continuity variation of the waveform data, and recording the state. For example, the voltage waveform data, composed of the sampling voltages, is analyzed. If the voltage is gradually rising and the voltage value is greater than the initial voltage, then it is judged as the start of the generator/engine.

In addition, if the voltage is gradually rising and the voltage value is greater than the initial voltage, the stable ripple can be detected so that it is judged as the start of the generator/engine.

Step S62 is a comprehensive judging step of performing the judgment according to the state of the start or stop of the vehicle engine, the state of the external auxiliary input signal, and the output state of the current control signal, and accordingly determining to light or extinguish the daytime running light, or to control the daytime running light to enter the low-luminance lighting state to serve as the position light.

For example, when the vehicle starts and no external auxiliary input signal is present, the daytime running light is automatically turned on. On the contrary, if the external auxiliary signal is inputted, the daytime running light is not allowed to light. At this time, the signal outputted to the daytime running light driving circuit may be in the off state or the control signal is outputted to make the driving circuit to light the daytime running light in the low-power low-luminance position light mode so that the daytime running light has the position light function. In addition, when the vehicle starts, the processing unit still continuously reads the sampling voltage data and calculates the average operation voltage of the battery.

When the vehicle does not start, it is also possible to continuously sample and record the voltage waveform of the battery.

When the daytime running light is lighting and the external auxiliary input signal is detected, the daytime running light be turned off or lights in the low-luminance position light mode. After the external auxiliary input signal disappears, the daytime running light again lights or the luminance is adjusted from the luminance of the position light to the luminance of the daytime running light.

In addition, when the engine or generator stops, the voltage ripple may decrease or disappear, and the voltage value, obtained from the sampling voltages, may be equal to or smaller than the initial voltage of the battery. So, the daytime running light can be turned off immediately.

Furthermore, when the engine or generator stops, the voltage ripple may decrease or disappear but the DC voltage is still equal to or higher than the initial voltage. At this time, the voltage waveform, obtained from the neighboring sampling voltages, is falling, and the voltage may be higher than the initial voltage. Thus, it is judged that the engine or generator has extinguished, so that the daytime running light can be turned off immediately.

According to the disclosed contents in steps S50 to S62, the sampling voltage waveform may be shown in FIG. 5 or 6. Each of the points P1 to Pn is the sampling point.

Thus, the invention does not utilize the hardware comparator and the predetermined constant reference voltage to serve as the reference for judgement. So, it is possible to eliminate the drawback of incapability of obtaining the overall waveform variation data, wherein the drawback is caused by the predetermined comparison value and the part errors.

Furthermore, the sampling voltage data is continuously recorded in the memory and is concurrently calculated to analyze the waveform variation. For example, when the voltage waveform, composed of the sampling voltages, is rising and the voltage value is greater than the initial voltage and the stable ripple can be detected, the engine or generator may be judged as entering the starting state. Alternatively, when the sampling voltage ripple decreases or even becomes zero and the voltage waveform is falling, the engine or generator can be judged as extinguished. So, it is possible to precisely judge whether the vehicle has started and whether the generator operates, so that the daytime running light can be truly controlled to light or off.

Thus, the invention judges whether the vehicle starts and whether the generator operates according to the variation of the voltage waveform per unit time.

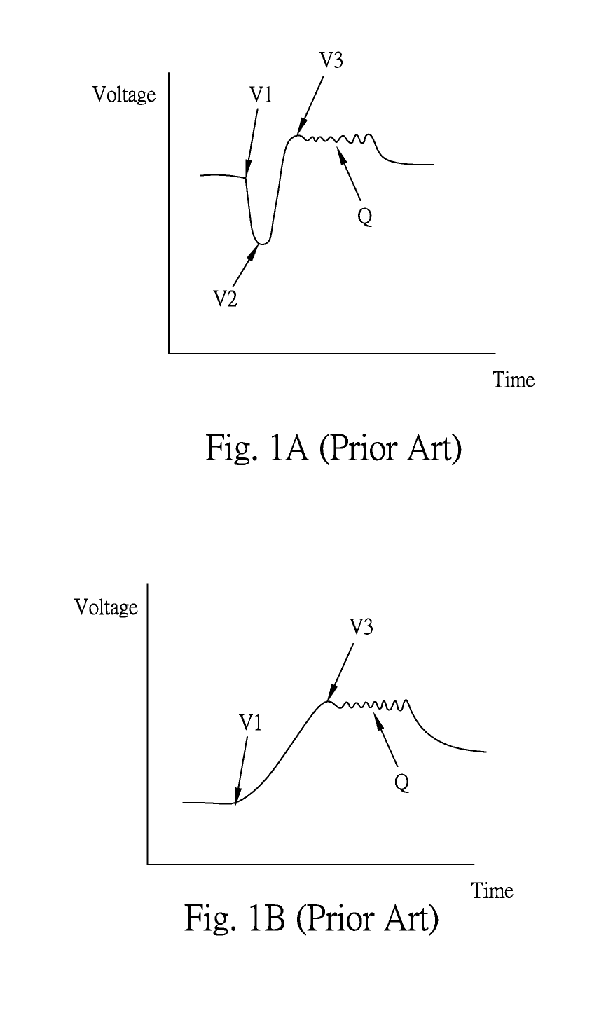

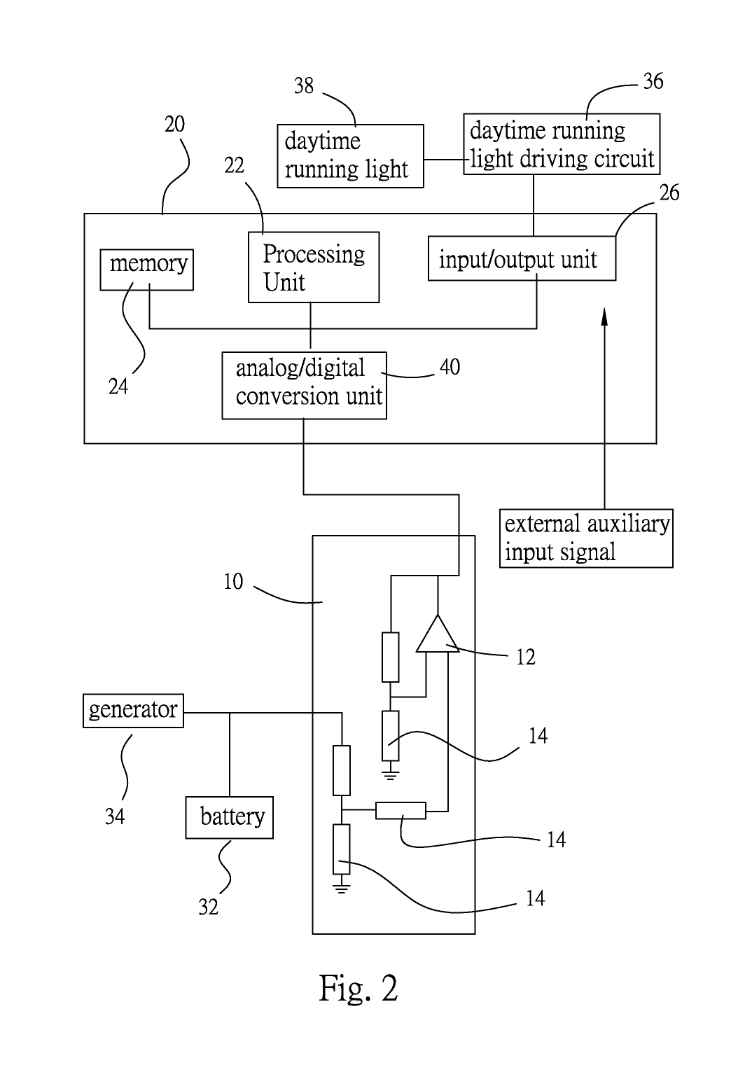

More particularly, regarding to the output waveforms of different voltages (e.g., the waveforms of FIGS. 1 and 2 or other similar waveforms), using the method of the invention still can precisely judge whether the generator or engine has started or stopped.

The sampling module can continuously perform sampling when the vehicle engine or generator stops and when the engine or generator has started. In addition, the processing unit still continuously reads the sampling voltage data, and converts it into data to be saved, so that the average operation voltage of the battery can be obtained, the voltage range and trend of each working mode can be further corrected without performing the work with only one constant. So, even if the battery is aging or changing by the climate, the usage of the invention still cannot be affected.

Furthermore, the invention may further adopt the design of one integrated circuit (IC), in which various devices are integrated, wherein the IC has the power sleep mode, in which the power consumption is reduced to the extremely small amount when the invention is in the idle or standby mode. More particularly, after the vehicle engine stops, the power consumption needs to be reduced to the extremely small amount, so that the battery power cannot be depleted and the vehicle still can normally start after the vehicle has stopped for a period of time.

What is claimed is:

1. A control device for controlling a daytime running light of a vehicle, the control device being connected to a battery of the vehicle and a daytime running light driving circuit, and for continuously reading an external auxiliary input signal and automatically lighting or extinguishing the daytime running light of the vehicle, characterized in that the control device comprises:
a sampling module, which is electrically connected to the battery of the vehicle, and continuously samples a voltage of the battery to obtain sampling voltage data: and
a controller, which is electrically connected to the sampling module, and has a processing unit electrically connected to a memory and an input/output unit, wherein the input/output unit continuously reads the external auxiliary input signal and outputs a signal to the daytime running light driver, wherein each of the sampling voltage data, obtained by the sampling module, is continuously recorded in the memory of the controller, and the processing unit calculates and analyzes a continuity variation of a sampling voltage.

2. The control device according to claim 1, characterized in that the control device further comprises a daytime running light driving circuit, which is electrically connected to the input/output unit and the daytime running light.

3. The control device according to claim 1, characterized in that the control device further comprises an analog/digital converter, which is disposed in the controller and electrically connected to the processing unit.

4. The control device according to claim 1, characterized in that the external auxiliary input signal is selected from a signal of a main light or a position light.

5. A method for controlling a daytime running light of a vehicle, characterized in that the method comprising the steps of:
reading and saving an output signal and an external auxiliary input signal;
continuously sampling a voltage of a battery, and obtain a plurality of sampling voltage data;
continuously recording the sampling voltage data and voltage waveforms of sampling voltages in a memory of a controller;
performing analysis and calculation on continuity variation of the voltage waveforms of the sampling voltages using a processing unit of the controller;
judging whether the vehicle starts according to analysis and calculation results of the continuity variation of the voltage waveforms of the sampling voltages;
automatically turning on the daytime running light when the vehicle starts and no external auxiliary input signal is present; and
continuously sampling and recording a voltage of the battery when the vehicle does not start.

6. The method according to claim 5, wherein the voltage is continuously sampled when the vehicle starts, and the processing unit still continuously reads the sampling voltages and calculates an average operation voltage of the battery.

7. The method according to claim 5, characterized in that in the step of performing analysis and calculation on the continuity variation of the voltage waveforms of the sampling voltages, the vehicle is judged as starting when the continuity variation of the voltage waveforms of the sampling voltages is rising, and a voltage value of the battery is greater than an initial voltage value of the battery after the voltage waveforms of the sampling voltages stops rising.

8. The method according to claim 7, characterized in that a stable ripple can be detected after the voltage waveform stops rising.

9. The method according to claim 5, characterized in that in the step of performing analysis and calculation on the continuity variation of the voltage waveforms of the sampling voltages, the daytime running light be turned off when a voltage ripple of the sampling voltage decreases and a voltage value obtained from the sampling voltage is equal to or smaller than an initial voltage of the battery.

10. The method according to claim 5, characterized in that in the step of performing analysis and calculation on the continuity variation of the voltage waveforms of the sampling voltages, the daytime running light be turned off when a voltage ripple of the sampling voltage disappears, and a voltage value, obtained from the sampling voltage, is equal to or smaller than an initial voltage of the battery.

11. The method according to claim 5, characterized in that in the step of performing analysis and calculation on the continuity variation of the voltage waveforms of the sampling voltages, the daytime running light be turned off when a voltage ripple of the sampling voltage decreases and a voltage waveform of the sampling voltages is falling.

12. The method according to claim 5, characterized in that in the step of performing analysis and calculation on the continuity variation of the voltage waveforms of the sampling voltages, the daytime running light be turned off when a voltage ripple of the sampling voltage disappears and a voltage waveform of the sampling voltage is falling.
